(19) United States
(12) Patent Application Publication
(10) Pub. No.: US 2025/0079224 A1
(43) Pub. Date: Mar. 6, 2025

(54) METHOD FOR PRODUCING SEMICONDUCTOR COMPONENTS FROM A WAFER USING A CARRIER WAFER

(71) Applicant: Robert Bosch GmbH, Stuttgart (DE)

(72) Inventors: Bernhard Polzinger, Stuttgart (DE); Christian Foerster, Reutlingen (DE); Jens Buettner, Reutlingen (DE); Karl Schuell, Reutlingen (DE); Kristina Vogt, Muenchingen (DE)

(21) Appl. No.: 18/797,575

(22) Filed: Aug. 8, 2024

(30) Foreign Application Priority Data
Sep. 4, 2023 (DE) 10 2023 208 478.3

(51) Int. Cl. H01L 21/683; B33Y 10/00; B33Y 30/00; B33Y 40/20; B33Y 80/00; B41M 5/00; H01L 21/304

(52) U.S. Cl. CPC H01L 21/6835; B33Y 80/00; B41M 5/0047; H01L 21/304; B33Y 10/00; B33Y 30/00; B33Y 40/20

(57) ABSTRACT

A method for producing semiconductor components, in particular power semiconductor components, from a wafer. The method includes: providing a wafer substrate, processing a structured wafer surface, applying a carrier wafer onto the wafer substrate, and reducing a thickness of the wafer substrate by means of wafer thinning.

### CROSS REFERENCE

The present application claims the benefit under 35 U.S.C. § 119 of German Patent Application No. DE 10 2023 208 478.3 filed on Sep. 4, 2023, which is expressly incorporated herein by reference in its entirety.

### FIELD

The present invention relates to a method for producing semiconductor components from a wafer using a carrier wafer, in particular a carrier wafer applied using a dam-and-fill process step.

### BACKGROUND INFORMATION

The manufacturing of a power semiconductor or semiconductor chip generally involves processing a wafer consisting of the material silicon (Si), silicon carbide or even sapphire and having a diameter of 150 mm, 200 mm or 300 mm, for example, over multiple individual steps. For manufacturing products in the field of MEMS and power semiconductor technologies, bonding substrates onto the wafer, for example to support very thin grinding of the wafer for performance reasons during the production process, is described in the related art. Providing a temporary carrier wafer made of robust material, such as quartz or silicon carbide, serves, among other things, to mechanically stabilize and simplify the handling of the wafer during processing. This also makes it possible to minimize wafer bending or so-called wafer bow. In particular wafers comprising deep trench structures or thick passivations and metallizations, which are the cause of wafer bow, can hardly be processed without a carrier wafer at chip thicknesses of less than 150 μm.

A disadvantage of the conventional methods is that extreme thinning of the wafers and substrates made of a wide variety of materials or multiple bonding (wafer stacks) leads to enormous stresses, especially in connection with thick layers such as metals, passivations and the deep trenches commonly used in power semiconductor technology, which makes the substrates so fragile that they cannot be further processed at all or only with a great amount of effort.

### SUMMARY

The present invention relates to a method for producing semiconductor components, in particular power semiconductor components, from a wafer. According to an example embodiment of the present invention, the method comprises the following steps:
providing a wafer substrate,
processing a structured wafer surface,
applying a carrier wafer onto the wafer substrate, and reducing a thickness of the wafer substrate by wafer thinning, wherein, according to the present invention, the carrier wafer is applied to the wafer surface using a dam-and-fill process step.

Advantageous further developments of the method according to the present invention for producing a plurality of semiconductor components from a wafer are disclosed herein.

Applying the carrier wafer to the wafer surface according to the present invention using a dam-and-fill process step or dam-and-fill process makes it possible to very effectively apply a wafer-stabilizing carrier layer to the finished processed wafer front side and thus mechanically stabilize the wafer in the following method steps, in particular during wafer thinning to reduce the substrate thickness. In addition to a simple application process, providing the carrier wafer according to the present invention also compensates stresses in the system. In contrast to purely additively produced carrier layers, a substantially higher filled layer thickness can be applied, which offers significant advantages in terms of shrinkage behavior during curing and with respect to a possible CTE mismatch between the carrier system and the wafer. The printed carrier layer also serves as an insulator, which reduces the risk of electrical flashover during electrical testing at breakdown voltages up to approximately 1600V and thus enables the use of a multiple test head for a higher test speed. Moreover, unlike other existing carrier technologies, the carrier can remain on the wafer until the final process step of wafer dicing or dividing the wafer into individual semiconductor components, which significantly simplifies the handling of the ultra-thin wafers in the final process sequences, increases processability and reduces defect costs. The method according to the present invention thus enables optimized process management and a more reliable production of semiconductor components.

According to an example embodiment of the present invention, the dam-and-fill process step advantageously includes applying at least one delimiting frame or edge structure in the form of a dam which has a predefined height and encloses a volume conventional digital printing technology, and filling the volume created or delimited by the frame structure with a filler material, preferably using a conventional dispensing or a dispensing step. The frame structure and the filling can be cured individually or together in a conventional manner, for example by means of UV or thermally.

The application of the ink to provide the dam or the frame structure can occur in a conventional manner using a suitable printhead which is disposed such that it can move relative to the wafer surface or a work surface supporting the wafer. This step advantageously includes applying an organic or inorganic ink and subsequent curing. An organic, for example polymer-based, or inorganic ink with a preferred layer thickness of 5 to 25 μm is advantageously printed onto the finished structured wafer upper side here. The ink can advantageously contain organic and/or inorganic, e.g., mineral or ceramic, fillers to improve the thermal and mechanical properties.

A filler material, preferably with low shrinkage and a low coefficient of thermal expansion (CTE) is advantageously filled into the volume delimited by the frame structure as a carrier layer using conventional dispensing step. The filler material can then be leveled and/or cured using a leveling process such as shaking or ultrasound.

According to an example embodiment of the present invention, The thus created carrier wafer serves as a mechanical carrier during backthinning and backside metallization as well as the handling processes in between, and does not deform, is high vacuum-suitable and temperature-stable. The carrier wafer can be removed again before or during a wafer separation process using a wafer dicing saw or a laser. The carrier wafer can be removed in a water or solvent bath, for example, and/or by adding additives. Alternatively, the carrier wafer can be removed by thermal or optical excitation.

According to an example embodiment of the present invention, applying the carrier wafer can include multiple dam-and-fill process steps for applying multiple superimposed layers, which are applied sequentially and with respective subsequent curing. The application is advantageously carried out in such a way that a carrier wafer with a layer thickness of 5 to 500 μm is provided.

According to an example embodiment of the present invention, the dam-and-fill process step can advantageously include applying at least one frame structure that surrounds a metallization surface of the wafer surface in order to provide openings in the filler material. An additional inner frame structure that surrounds the respective metallization surface can be applied or printed here as a dam within an outer frame structure before a volume between the frame structures is filled in the dam-and-fill process. The respective metallization surface is therefore not covered by the carrier wafer, so that the wafer can be electrically contacted and tested during the further process. The wafer can thus continue to be tested both after backthinning and after the sputtering of the backside metallization.

The thus provided openings in the filler material of the carrier wafer can further advantageously be filled or printed using a separate, removable filler or support material, preferably during the dam-and-fill process step and using digital printing technology. This makes it possible to improve the contour sharpness of the carrier wafer in the region of the openings, so that smaller openings can be realized, especially with higher layer thicknesses. The support material can be removed again after the carrier wafer has been applied, for example in a water or solvent bath, or with the aid of thermal excitation.

According to an example embodiment of the present invention, the method can further advantageously include selectively removing the filler material, in which filler material of the carrier wafer disposed above a metallization surface disposed on the wafer surface is removed from said metallization surface. The applied filler material can thus be selectively removed in the region of a metallization surface, for instance by laser impingement, so that said surface can be electrically contacted and tested during the further process.

After the application of the printed carrier wafer, the method can advantageously include a leveling step in which a predefined and preferably uniform layer thickness of the carrier wafer is created or achieved on the wafer surface. This can be done with a doctor blade, for example. This in particular also makes it possible to remove excess ink or smooth the surface of the applied layer or the applied layers.

According to an example embodiment of the present invention, in the dam-and-fill process step, a frame structure and/or a filler material is advantageously applied to an outer rounded region of the wafer substrate in such a way that the rounded region is evened out and in particular made level with a surface of the wafer substrate. This allows a rounding in the edge region to be evened out and a flat carrier wafer to be applied closer to the edge region. This in particular makes it possible to avoid the risk of chipping during the backthinning process, because the carrier wafer can otherwise not apply backpressure in these regions.

According to an example embodiment of the present invention, the method can further advantageously include applying a support layer which is water-soluble and preferably laterally delimited by a frame structure to the wafer surface, preferably by digital printing technology, prior to applying a filler material of the carrier wafer. This layer can be applied or removed by the process fluid in a separation process, which also makes it easier to remove the carrier wafer layers separated in the process from the individual semiconductor components.

According to an example embodiment of the present invention, the method can moreover also advantageously include applying an abrasive film over the carrier wafer that in particular covers openings disposed in said carrier wafer. This makes it possible to prevent the support layer from dissolving prematurely during wafer thinning or during the backthinning process in which process fluids are used as well.

According to an example embodiment of the present invention, the step of applying the carrier wafer takes place before a wafer thinning or backthinning process of the wafer, in which the wafer is reduced from its original wafer thickness to a component thickness desired or needed for the later application of the semiconductor components or chips. This can be done according to the specific requirements of the manufacturing process and the desired thickness of the wafer, for instance by grinding, chemical mechanical polishing (CMP) or etching. In a preferred embodiment, the wafer is backthinned to a thickness of less than 300 μm, more preferably to less than 200 μm, even more preferably to less than 150 μm.

The present invention also relates to a semiconductor component, in particular a power semiconductor component, that is or can be produced according to the method of the present invention described above.

Further advantages and details of the present invention will emerge from the following description of preferred example embodiments of the present invention and from the merely schematically illustrated figures.

### BRIEF DESCRIPTION OF THE DRAWINGS

FIG. 1A-1E show method steps of a first preferred embodiment of the method according to the present invention by means of schematic side views of the wafer.

FIG. 2A-2C show method steps of another preferred embodiment of the method of the present invention with the application of a separate, soluble support layer.

FIG. 3A-3C show detail views of an application of the carrier wafer to an edge region of the wafer, according to an example embodiment of the present invention.

### DETAILED DESCRIPTION OF EXAMPLE EMBODIMENTS

The same elements or elements having the same function are provided with the same reference numbers in the figures.

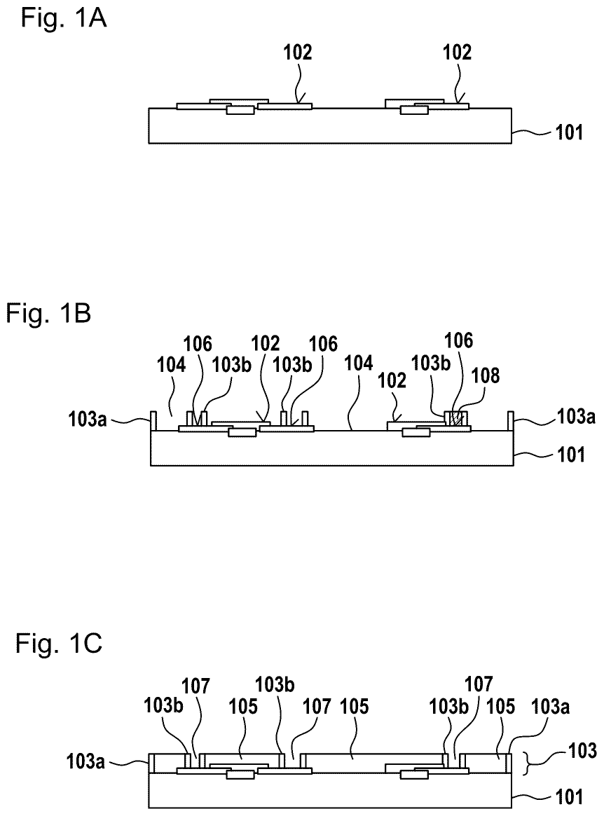

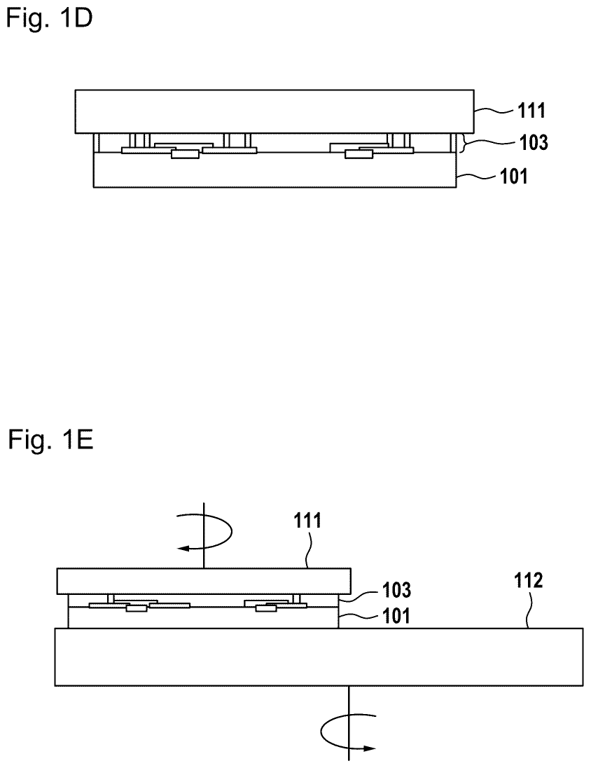

As shown in FIG. 1A, a wafer substrate 101, for example consisting of silicon (Si), silicon carbide (SiC) or gallium nitride (GaN), is provided first as a basis for processing the semiconductor components to be formed on the wafer. The desired or process-specified layers and structures 102 for producing semiconductor components such as transistors, diodes or integrated circuits are then formed on a wafer substrate surface in a conventional manner.

As shown in FIGS. 1B and 1C, the next step involves applying a carrier wafer 103 to the wafer substrate 101 by means of a dam-and-fill process step. First, dam or a frame structure 103a, 103b made of an organic or inorganic ink with a typical layer thickness of 5-25 μm and a preferred wall thickness of preferably 50 to several 100 μm is printed onto the finished processed wafer surface in a structured manner, preferably using digital printing technology or inkjet technology. The ink is cured or sintered while printing or after printing a layer (e.g. by means of UV or thermally).

After printing, an optional leveling step can be carried out, for example using a doctor blade, in order to produce layers that are as flat as possible. To be able to achieve greater layer thicknesses, e.g. in the range of 50-500 μm, this process is repeated several times, analogous to conventional inkjet-based 3D printing. A final hardening or sintering step can optionally be carried out after printing the respective layers to achieve complete cross-linking and improve the mechanical properties. The ink preferably contains organic and/or inorganic, e.g. mineral or ceramic, fillers to improve the thermal and mechanical properties.

A volume 104 delimited by the frame structure is filled with highly filled filler material 105 by means of dispensing. The filler material can be an underfill material or can be configured as a globe-top and advantageously exhibits low shrinkage and a low coefficient of thermal expansion (CTE). The filler material can then be leveled and/or cured using a leveling process such as shaking or ultrasound.

The filler material 105 is preferably introduced in such a way that openings 107 for metallization surfaces 106 of the wafer remain free. The applied frame structure preferably comprises an inner frame structure 103b that surrounds one or more metallization surfaces 106 of the structured wafer surface 102.

A removable filler material or support material 108 can optionally be applied, and in particular printed, in the region of the openings 107 in parallel with the application of the carrier wafer 103. This is shown as an example in FIG. 1B for the right opening. This makes it possible to improve the contour sharpness of the carrier wafer 103 in the region of the openings 107, so that smaller openings can be realized, especially with higher layer thicknesses. The support material 108 can be removed again after the carrier wafer 103 has been printed, for example in a water bath, a solvent bath or with the aid of thermal excitation.

As shown in FIG. 1D, an abrasive film 101 can optionally be applied to the wafer front side prior to a backthinning step of the wafer substrate 101.

As shown in FIG. 1E, the method includes the further step of backthinning or wafer thinning, in which the wafer substrate 101 is reduced to a predefined thickness. The backthinning can, for instance, be carried out by means of grinding with a suitable abrasive 112.

In a preferred embodiment, the wafer is backthinned to a thickness of less than 300 μm, preferably to less than 200 μm, more preferably to less than 150 μm. After the backthinning process, the optionally applied abrasive film 101 can be removed and a metal contact can be applied to the back of the wafer.

In a subsequent not depicted production step, the wafer substrate 101 can be separated or singulated into individual semiconductor components.

Alternatively to the embodiment described above, the method can include covering the entire surface of the wafer surface 102 with filler material 105 within the printed frame structure 103a, in which case wafer thinning or a backthinning step takes place after the application of the carrier wafer 103. It is then possible to create openings 107 in the carrier wafer 103 by means of selective removal, for example by means of a laser, such that one or more metallization surfaces 106 disposed on the wafer surface are freed of the filler material of the carrier wafer 103 disposed above it in order to create contact for a wafer test.

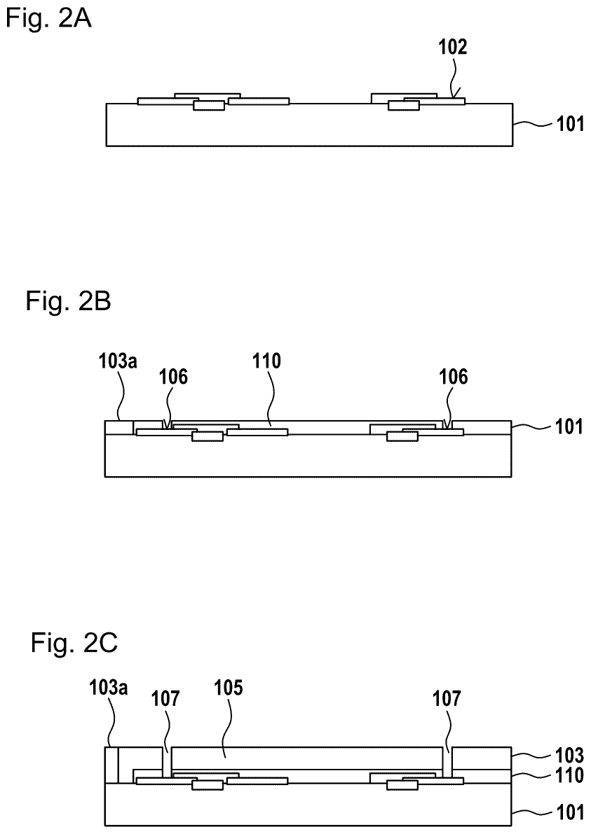

FIG. 2A to 2C show another preferred embodiment of the method. This differs from the method according to FIG. 1A-1E in that, after a structured wafer surface 102 is processed as shown in FIG. 1A, a detachable and in particular water-soluble support layer 110 is printed onto the wafer surface, preferably using digital printing technology. This can be done during application of the frame structure 103a using printing technology. In this case, the frame structure 103a preferably encloses the support layer 110 laterally. The carrier wafer 103 is then applied and formed using a dam-and-fill process step as shown schematically in FIG. 2C.

In a later separation step of the wafer, the support layer 110 can be applied or removed by the process fluid. This also removes the separated carrier wafer layer. The laterally provided frame structure 103a also protects the support layer 110 during the backthinning process, in which process fluids are used as well, so that the support layer 110 is not applied prematurely. An optional abrasive film 110 (see FIG. 1D) can additionally be disposed in the region of the openings 107 to protect the support layer 110 from contact with process fluid.

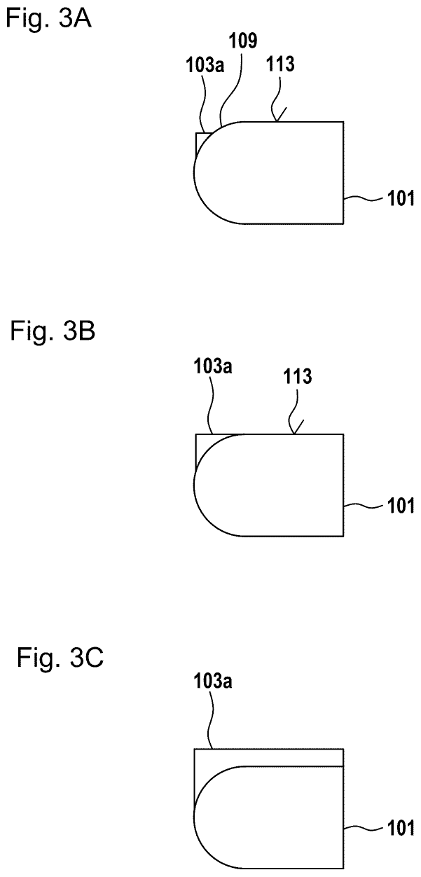

FIG. 3A-3C show an edge region 109 of the wafer substrate 101. This is rounded in the region of the first 100 to 300 μm, which increases the risk of chipping during the backthinning process of the wafer substrate. During the method according to the present invention, the frame structure 103a is advantageously applied or printed during the application of the carrier wafer 103 in such a way that the rounded region is evened out and in particular made level with a surface 113 of the wafer substrate. This can be achieved with a multilayer configuration or printing of the frame structure 103a as shown schematically in FIG. 3A to 3C. Leveling the rounded region 109 of the wafer 101 makes it possible to position the carrier wafer 103 closer to an outer wafer edge.

What is claimed is:

1. A method for producing semiconductor components including power semiconductor components, from a wafer, comprising the following steps:
providing a wafer substrate;
processing a structured wafer surface;
applying a carrier wafer onto the wafer substrate; and
reducing a thickness of the wafer substrate by wafer thinning;
wherein the carrier wafer is applied to the wafer surface using a dam-and-fill process step.

2. The method according to claim 1, wherein the dam-and-fill process step includes applying at least one frame structure to the wafer surface using digital printing technology and filling a volume delimited by the frame structure with a filler material by dispensing the filler material.

3. The method according to claim 1, wherein the dam-and-fill process step includes applying a frame structure that surrounds at least one metallization surface of the wafer surface to provide openings in the filler material.

4. The method according to claim 3, wherein the openings in the filler material of the carrier wafer are filled using a separate, removable filler material, using digital printing technology.

5. The method according to claim 1, wherein the method includes selectively removing filler material, using a laser, in which filler material of the carrier wafer disposed above at least one metallization surface disposed on the wafer surface is removed from the metallization surface.

6. The method according to claim 1, wherein the applying of the carrier wafer includes applying an organic or inorganic ink and subsequent curing.

7. The method according to claim 1, wherein the applying of the carrier wafer includes multiple dam-and-fill process steps for applying multiple superimposed layers, which are applied sequentially and with respective subsequent curing.

8. The method according to claim 1, wherein a frame structure and/or a filler material is applied to an outer rounded region of the wafer substrate in the dam-and-fill process step in such a way that a rounded region is evened out and made level with a surface of the wafer substrate.

9. The method according to claim 1, wherein the method includes applying a support layer which is water-soluble and laterally delimited by a frame structure to the wafer surface, by digital printing technology, prior to applying a filler material of the carrier wafer.

10. The method according to claim 9, wherein the method includes applying an abrasive film over the carrier wafer that covers openings disposed in the carrier wafer.

11. A semiconductor component produced by:
providing a wafer substrate;
processing a structured wafer surface;
applying a carrier wafer onto the wafer substrate; and
reducing a thickness of the wafer substrate by wafer thinning;
wherein the carrier wafer is applied to the wafer surface using a dam-and-fill process step.
